(19) United States
(12) Patent Application Publication
(10) Pub. No.: US 2016/0072000 A1
(43) Pub. Date: Mar. 10, 2016

(54) FRONT CONTACT HETEROJUNCTION PROCESS

(71) Applicant: David D. Smith, Campbell, CA (US)

(72) Inventor: David D. Smith, Campbell, CA (US)

(21) Appl. No.: 14/578,216

(22) Filed: Dec. 19, 2014

Related U.S. Application Data
(60) Provisional application No. 62/046,717, filed on Sep. 5, 2014.

(51) Int. Cl. H01L 31/18; H01L 31/0236; H01L 31/068; H01L 31/0368; H01L 31/0224

(52) U.S. Cl. CPC H01L 31/1804; H01L 31/03682; H01L 31/022425; H01L 31/0684; H01L 31/022466; H01L 31/02366; H01L 31/1864; H01L 31/1884; H01L 31/1872

(57) ABSTRACT

Methods of fabricating solar cells using improved front contact heterojunction processes, and the resulting solar cells, are described. In an example, a solar cell includes a substrate having first and second light-receiving surfaces. A tunnel dielectric layer is disposed on the first and second light-receiving surfaces. An N-type polycrystalline silicon layer is disposed on the portion of the tunnel dielectric layer disposed on the first light-receiving surface. A P-type polycrystalline silicon layer is disposed on the portion of the tunnel dielectric layer disposed on the second light-receiving surface. A transparent conductive oxide layer is disposed on the N-type polycrystalline silicon layer and on the P-type polycrystalline silicon layer. A first set of conductive contacts is disposed on the portion of the transparent conductive oxide layer disposed on the N-type polycrystalline silicon layer. A second set of conductive contacts is disposed on the portion of the transparent conductive oxide layer disposed on the P-type polycrystalline silicon layer.

### CROSS-REFERENCE TO RELATED APPLICATIONS

This application claims the benefit of U.S. Provisional Application No. 62/046,717, filed on Sep. 5, 2014, the entire contents of which are hereby incorporated by reference herein.

### TECHNICAL FIELD

Embodiments of the present disclosure are in the field of renewable energy and, in particular, methods of fabricating solar cells using improved front contact heterojunction processes, and the resulting solar cells.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIGS. 1-6 illustrate cross-sectional views of various stages in the fabrication of a solar cell, in accordance with an embodiment of the present disclosure, wherein:

FIG. 1 illustrates a provided substrate;

FIG. 2 illustrates the structure of FIG. 1 following texturizing of the light-receiving surfaces;

FIG. 3 illustrates the structure of FIG. 2 having a tunnel dielectric layer formed thereon;

FIG. 4 illustrates the structure of FIG. 3 following formation of first and second silicon layers;

FIG. 5 illustrates the structure of FIG. 4 following a high temperature anneal and deposition of a TCO layer; and

FIG. 6 illustrates the structure of FIG. 5 having conductive contacts formed thereon.

FIG. 7 is a flowchart listing operations in a method of fabricating a solar cell as corresponding to FIGS. 1-6, in accordance with an embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

Methods of fabricating solar cells using improved front contact heterojunction processes, and the resulting solar cells, are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are methods of fabricating solar cells. In one embodiment, a method of fabricating a solar cell involves providing a substrate having first and second light-receiving surfaces. The method also involves texturizing one or both of the first and second light-receiving surfaces. The method also involves forming a tunnel dielectric layer on the first and second light-receiving surfaces. The method also involves forming an N-type amorphous silicon layer on the portion of the tunnel dielectric layer on the first light-receiving surface, and forming a P-type amorphous silicon layer on the portion of the tunnel dielectric layer on the second light-receiving surface. The method also involves annealing the N-type amorphous silicon layer and the P-type amorphous silicon layer to form an N-type polycrystalline silicon layer and a P-type polycrystalline silicon layer, respectively. The method also involves forming a transparent conductive oxide layer on the N-type polycrystalline silicon layer and on the P-type polycrystalline silicon layer. The method also involves forming a first set of conductive contacts on the portion of the transparent conductive oxide layer on the N-type polycrystalline silicon layer, and a second set of conductive contacts on the portion of the transparent conductive oxide layer on the P-type polycrystalline silicon layer.

Also disclosed herein are solar cells. In an embodiment, a solar cell includes a substrate having first and second light-receiving surfaces. A tunnel dielectric layer is disposed on the first and second light-receiving surfaces. An N-type polycrystalline silicon layer is disposed on the portion of the tunnel dielectric layer disposed on the first light-receiving surface. The N-type polycrystalline silicon layer has grain boundaries. A P-type polycrystalline silicon layer is disposed on the portion of the tunnel dielectric layer disposed on the second light-receiving surface. The P-type polycrystalline silicon layer has grain boundaries. A transparent conductive oxide layer is disposed on the N-type polycrystalline silicon layer and on the P-type polycrystalline silicon layer. A first set of conductive contacts is disposed on the portion of the transparent conductive oxide layer disposed on the N-type polycrystalline silicon layer. A second set of conductive contacts is disposed on the portion of the transparent conductive oxide layer disposed on the P-type polycrystalline silicon layer.

In another embodiment, a solar cell includes a substrate having first and second light-receiving surfaces. A tunnel dielectric layer is disposed on the first and second light-receiving surfaces. An N-type polycrystalline silicon layer is disposed on the portion of the tunnel dielectric layer disposed on the first light-receiving surface. A corresponding N-type diffusion region is disposed in the substrate proximate to the N-type polycrystalline silicon layer. A P-type polycrystalline silicon layer is disposed on the portion of the tunnel dielectric layer disposed on the second light-receiving surface. A corresponding P-type diffusion region is disposed in the substrate proximate to the P-type polycrystalline silicon layer. A transparent conductive oxide layer is disposed on the N-type polycrystalline silicon layer and on the P-type polycrystalline silicon layer. A first set of conductive contacts is disposed on the portion of the transparent conductive oxide layer disposed on the N-type polycrystalline silicon layer. A second set of conductive contacts is disposed on the portion of the transparent conductive oxide layer disposed on the P-type polycrystalline silicon layer.

Embodiments described herein are directed to an improved front contact heterojunction process. State of the art approaches currently use an apparent thermal oxide followed by amorphous or microcrystalline silicon deposition and a transparent conductive oxide (TCO) and copper plating approach. Embodiments described below move the location of a thermal operation subsequent to the silicon deposition processes in order to fabricate a front polycrystalline silicon contact solar cell.

To provide context, state of the art approaches may involve growth of a high quality oxide and follow with an amorphous silicon layer deposition. There are several disadvantages to such an approach. The oxide is high quality, but the junction is at the surface of the device which renders surface preparation critical such that the films do not form on particles or contaminated regions, etc. Also, the amorphous silicon film absorbs a substantial amount of light. Third, there is not a high temperature treatment with phosphorous doping which can translate to a lifetime that will likely be limited to modest values. State of the art approaches could very well be improved by depositing the silicon film as microcrystalline which would alleviate the transparency issue, but none of the others. A lack of gettering could be alleviated by using high quality higher cost silicon. The junction at the surface issue would otherwise have to be dealt with by extremely good cleanliness of the factory and tools.

By contrast, in accordance with one or more embodiments described herein, a front contact process involves formation of a double sided textured wafer. Low temperature oxidation, either wet chemical or plasma oxidation for instance, and subsequent deposition of doped silicon films on opposite surfaces is then followed by a high temperature treatment. In an embodiment, then, an anneal is performed after the tunnel dielectric and silicon depositions. The high temperature treatment may be a rapid thermal anneal or a furnace anneal. In one embodiment, the process space is above approximately 900 degrees Celsius. Such processing may be implemented to break up the tunnel dielectric somewhat and to achieve the most benefit from gettering of metals into the highly doped polycrystalline silicon material. The process may be completed by forming a TCO layer and then forming contacts, e.g., by copper plating.

In an embodiment, advantages of approaches described herein may include enabling the ability to achieve a higher efficiency and the ability to use lower purity and, hence, lower cost silicon. Greater transparency of silicon films after crystallization is another potential advantage. Thermally diffusing a junction into an underlying substrate to remove metallurgical junctions at the wafer surface may be enabled. Approaches described may be implemented to minimize potential for undoped surfaces without passivating films. Metal gettering into doped polysilicon to improve lifetime may be another advantage.

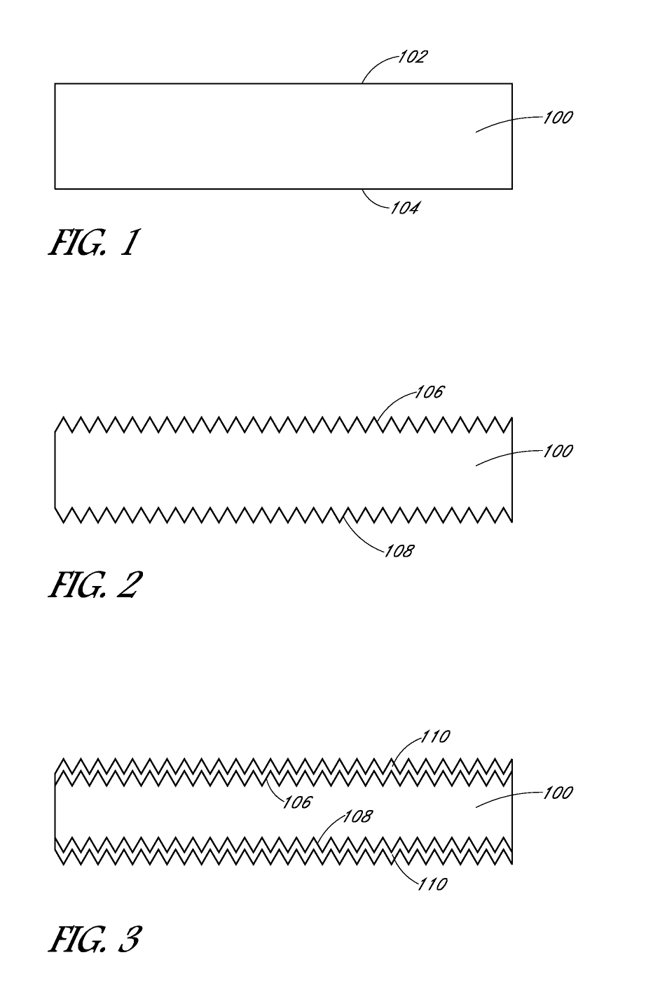

In an exemplary process flow, FIGS. 1-6 illustrate cross-sectional views of various stages in the fabrication of a solar cell, in accordance with an embodiment of the present disclosure. FIG. 7 is a flowchart 700 listing operations in a method of fabricating a solar cell, as corresponding to FIGS. 1-6, in accordance with an embodiment of the present disclosure.

Referring to operation 702 of flowchart 700 and to corresponding FIG. 1, a method of fabricating a solar cell involves providing a substrate 100. In an embodiment, the substrate 100 is an N-type monocrystalline silicon substrate. In an embodiment, the substrate 100 has a first light-receiving surface 102 and a second light-receiving surface 104.

Referring now to operation 704 of flowchart 700 and to corresponding FIG. 2, one or both of the light-receiving surfaces 102 and 104 are texturized to provide first texturized light-receiving surface 106 and second texturized light-receiving surface 108, respectively (both are shown as being texturized in FIG. 2). In an embodiment, a hydroxide-based wet etchant is employed to texturize the light receiving surfaces 102 and 104 of the substrate 100.

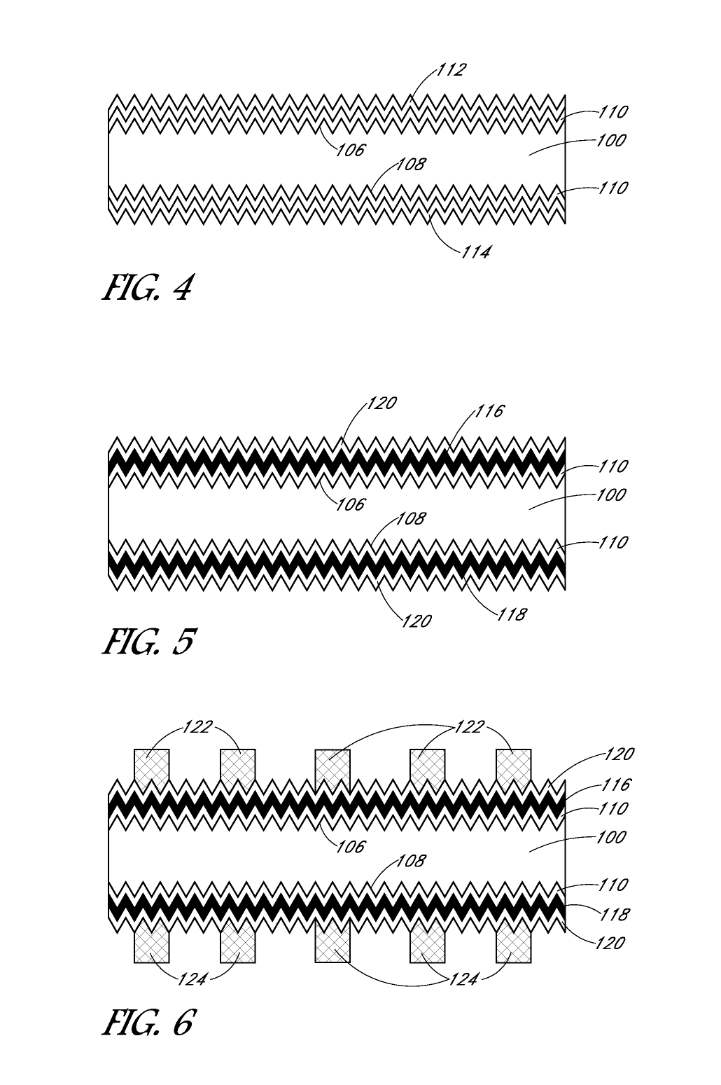

Referring now to operation 706 of flowchart 700 and to corresponding FIG. 3, a tunnel dielectric layer 110 is formed on the first texturized light-receiving surface 106 and the second texturized light-receiving surface 108. In an embodiment, the tunnel dielectric layer 110 is a wet chemical silicon oxide layer, e.g., formed from wet chemical oxidation of the silicon of the first texturized light-receiving surface 106 and the second texturized light-receiving surface 108. In another embodiment, the tunnel dielectric layer 110 is a deposited silicon oxide layer, e.g., formed from chemical vapor deposition on the first texturized light-receiving surface 106 and on the second texturized light-receiving surface 108. In another embodiment, the tunnel dielectric layer 110 is a thermal silicon oxide layer, e.g., formed from thermal oxidation of the silicon of the first texturized light-receiving surface 106 and the second texturized light-receiving surface 108. In other embodiments, the tunnel dielectric layer is a nitrogen doped SiO₂ layer or other dielectric material such as a silicon nitride layer.

Referring now to operation 708 of flowchart 700 and to corresponding FIG. 4, a first silicon layer 112 of a first conductivity type is formed on the portion of the tunnel dielectric layer 110 formed on the first texturized light-receiving surface 106. A second silicon layer 114 of a second conductivity type is formed on the portion of the tunnel dielectric layer 110 formed on the second texturized light-receiving surface 108. In an embodiment, the first silicon layer 112 is an N-type amorphous silicon layer, and the second silicon layer 114 is a P-type amorphous silicon layer. In an embodiment, the first silicon layer 112 and the second silicon layer 114 are formed by chemical vapor deposition.

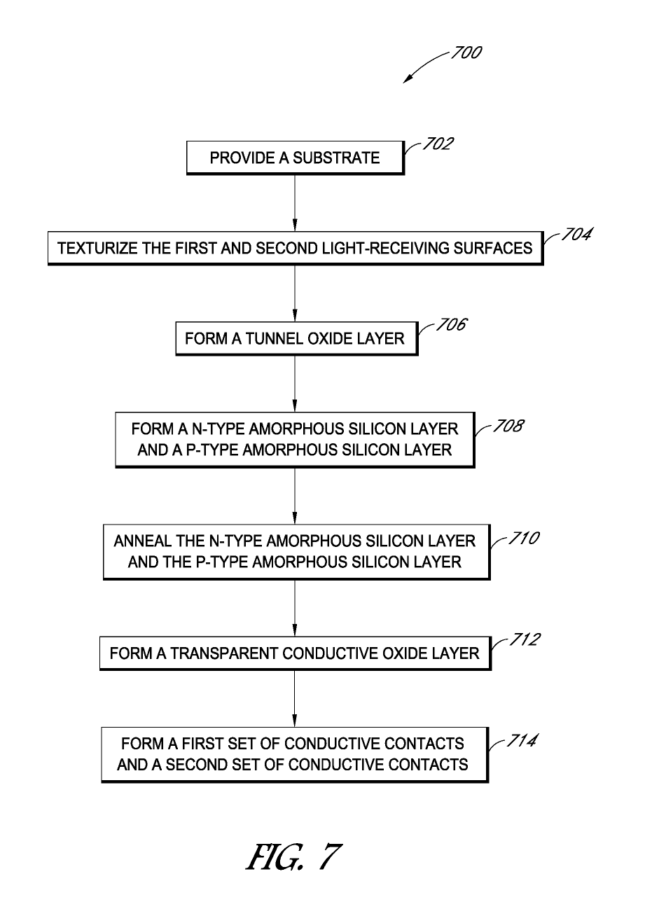

Referring now to operation 710 of flowchart 700 and to corresponding FIG. 5, a high temperature anneal process is used to crystallize the first silicon layer 112 and the second silicon layer 114 to form first polycrystalline silicon layer 116 and second polycrystalline silicon layer 118, respectively. In an embodiment, the first polycrystalline silicon layer 116 is an N-type polycrystalline silicon layer, and the second polycrystalline silicon layer 118 is a P-type polycrystalline silicon layer. In one such embodiment, grain boundaries are formed in the N-type polycrystalline silicon layer and in the P-type polycrystalline silicon layer. In an embodiment, the high temperature anneal is performed at a temperature above 900 degrees Celsius. In an embodiment, the high temperature anneal process drives dopants from the silicon layers 112/116 and 114/118 partially into the substrate 100 during the annealing process. In one such embodiment, a P-type diffusion regions forms in the portion of the substrate 100 proximate to the P-type polycrystalline silicon layer, while an N-type diffusion regions forms in the portion of the substrate 100 proximate to the N-type polycrystalline silicon layer.

Referring now to operation 712 of flowchart 700 and again to corresponding FIG. 5, a transparent conductive oxide (TCO) layer 120 is formed on the first polycrystalline silicon layer 116 and on the second polycrystalline silicon layer 118. In an embodiment, the TCO layer 120 is a layer of indium tin oxide (ITO).

Referring now to operation 714 of flowchart 700 and to corresponding FIG. 6, a first set of conductive contacts 122 is formed on the portion of the TCO layer formed on the first polycrystalline silicon layer 116. A second set of conductive contacts 124 is formed on the portion of the TCO layer formed on the second polycrystalline silicon layer 118. In an embodiment, the first set of conductive contacts 122 and the second set of conductive contacts 124 is formed by first forming a metal seed layer and then electroplating a metal such as copper in a mask formed on the metal seed layer. In another embodiment, the first set of conductive contacts 122 and the second set of conductive contacts 124 is formed by a printed paste process, such as a printed silver paste process. The resulting structure of FIG. 6 can be viewed as a completed or almost completed solar cell, which may be included in a solar module.

Overall, although certain materials are described specifically above, some materials may be readily substituted with others with other such embodiments remaining within the spirit and scope of embodiments of the present disclosure. For example, in an embodiment, a different substrate material ultimately provides a solar cell substrate. In one such embodiment, a group III-V material substrate ultimately provides a solar cell substrate. Furthermore, it is to be appreciated that, where N+ and P+ type doping is described specifically, other embodiments contemplated include the opposite conductivity type, e.g., P+ and N+ type doping, respectively.

Thus, methods of fabricating solar cells using improved front contact heterojunction processes, and the resulting solar cells, have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A method of fabricating a solar cell, the method comprising:
providing a substrate having first and second light-receiving surfaces;
texturizing one or both of the first and second light-receiving surfaces;
forming a tunnel dielectric layer on the first and second light-receiving surfaces;
forming an N-type amorphous silicon layer on the portion of the tunnel dielectric layer on the first light-receiving surface, and forming a P-type amorphous silicon layer on the portion of the tunnel dielectric layer on the second light-receiving surface;
annealing the N-type amorphous silicon layer and the P-type amorphous silicon layer to form an N-type polycrystalline silicon layer and a P-type polycrystalline silicon layer, respectively;
forming a transparent conductive oxide layer on the N-type polycrystalline silicon layer and on the P-type polycrystalline silicon layer; and
forming a first set of conductive contacts on the portion of the transparent conductive oxide layer on the N-type polycrystalline silicon layer, and a second set of conductive contacts on the portion of the transparent conductive oxide layer on the P-type polycrystalline silicon layer.

2. The method of claim 1, wherein annealing the N-type amorphous silicon layer and the P-type amorphous silicon layer comprises heating the substrate to a temperature above approximately 900 degrees Celsius.

3. The method of claim 1, wherein annealing the N-type amorphous silicon layer and the P-type amorphous silicon layer comprises forming grain boundaries in the resulting N-type polycrystalline silicon layer and P-type polycrystalline silicon layer.

4. The method of claim 1, wherein forming the tunnel dielectric layer comprises performing wet chemical oxidation of the first and second light-receiving surfaces.

5. The method of claim 1, wherein forming the tunnel dielectric layer comprises depositing a silicon oxide layer by chemical vapor deposition.

6. The method of claim 1, wherein annealing the N-type amorphous silicon layer and the P-type amorphous silicon layer comprises forming a P-type diffusion region in the substrate proximate to the resulting P-type polycrystalline silicon layer, and comprises forming an N-type diffusion region in the substrate proximate to the resulting N-type polycrystalline silicon layer.

7. The method of claim 1, wherein texturizing one or both of the first and second light-receiving surfaces comprises texturizing only one of the first and second light-receiving surfaces.

8. The method of claim 1, wherein texturizing one or both of the first and second light-receiving surfaces comprises texturizing both of the first and second light-receiving surfaces.

9. The method of claim 1, wherein forming the transparent conductive oxide layer comprises forming a layer of indium tin oxide (ITO).

10. The method of claim 1, wherein forming the N-type amorphous silicon layer comprises forming an N-type amorphous silicon layer by chemical vapor deposition, and wherein forming the P-type amorphous silicon layer comprises forming an P-type amorphous silicon layer by chemical vapor deposition.

11. A solar cell fabricated according to the method of claim 1.

12. A solar cell, comprising:
a substrate having first and second light-receiving surfaces;
a tunnel dielectric layer disposed on the first and second light-receiving surfaces;
an N-type polycrystalline silicon layer disposed on the portion of the tunnel dielectric layer disposed on the first light-receiving surface, wherein the N-type polycrystalline silicon layer comprises grain boundaries;
a P-type polycrystalline silicon layer disposed on the portion of the tunnel dielectric layer disposed on the second light-receiving surface, wherein the P-type polycrystalline silicon layer comprises grain boundaries;
a transparent conductive oxide layer disposed on the N-type polycrystalline silicon layer and on the P-type polycrystalline silicon layer;
a first set of conductive contacts disposed on the portion of the transparent conductive oxide layer disposed on the N-type polycrystalline silicon layer; and
a second set of conductive contacts disposed on the portion of the transparent conductive oxide layer disposed on the P-type polycrystalline silicon layer.

13. The solar cell of claim 12, wherein one or both of the first and second light-receiving surfaces is texturized.

14. The solar cell of claim 12, wherein the transparent conductive oxide layer is a layer of indium tin oxide (ITO).

15. The solar cell of claim 12, wherein the substrate is a monocrystalline silicon substrate, and wherein the tunnel dielectric layer is a silicon oxide layer.

16. A solar cell, comprising:
a substrate having first and second light-receiving surfaces;
a tunnel dielectric layer disposed on the first and second light-receiving surfaces;
an N-type polycrystalline silicon layer disposed on the portion of the tunnel dielectric layer disposed on the first light-receiving surface, and a corresponding N-type diffusion region disposed in the substrate proximate to the N-type polycrystalline silicon layer;
a P-type polycrystalline silicon layer disposed on the portion of the tunnel dielectric layer disposed on the second light-receiving surface, and a corresponding P-type diffusion region disposed in the substrate proximate to the P-type polycrystalline silicon layer;
a transparent conductive oxide layer disposed on the N-type polycrystalline silicon layer and on the P-type polycrystalline silicon layer;
a first set of conductive contacts disposed on the portion of the transparent conductive oxide layer disposed on the N-type polycrystalline silicon layer; and
a second set of conductive contacts disposed on the portion of the transparent conductive oxide layer disposed on the P-type polycrystalline silicon layer.

17. The solar cell of claim 16, wherein the N-type polycrystalline silicon layer comprises grain boundaries, and wherein the P-type polycrystalline silicon layer comprises grain boundaries.

18. The solar cell of claim 16, wherein one or both of the first and second light-receiving surfaces is texturized.

19. The solar cell of claim 16, wherein the transparent conductive oxide layer is a layer of indium tin oxide (ITO).

20. The solar cell of claim 16, wherein the substrate is a monocrystalline silicon substrate, and wherein the tunnel dielectric layer is a silicon oxide layer.
